(19) United States
(12) Patent Application Publication
(10) Pub. No.: US 2018/0202041 A1
(43) Pub. Date: Jul. 19, 2018

(54) METHOD AND SYSTEM FOR MANUFACTURING A STAINLESS STEEL SUBSTRATE WITH A CORROSION RESISTANT COATING

(71) Applicant: GM GLOBAL TECHNOLOGY OPERATIONS LLC, Detroit, MI (US)

(72) Inventors: Smuruthi Kamepalli, Rochester, MI (US); Robert J Moses, Oxford, MI (US); Balasubramanian Lakshmanan, Rochester Hills, MI (US)

(21) Appl. No.: 15/408,583

(22) Filed: Jan. 18, 2017

(51) Int. Cl. C23C 16/02

(52) U.S. Cl. CPC C23C 16/0209

(57) ABSTRACT

A method and system for manufacturing a corrosion resistant performs the steps of: (1) providing a substrate; (2) moving the substrate to a cleaning chamber via the conveyor; (3) cleaning the substrate; (4) moving the substrate into a first pressure chamber; (5) moving the substrate out of the first pressure chamber; (5) determining a first temperature change in the substrate at the first pressure chamber; (6) adjusting a second heat source at a second pressure chamber based on the first temperature change; and (7) moving the substrate into the second pressure chamber. The system includes at least one pressure chamber housing a heat source wherein a temperature sensor is disposed at the inlet and at the outlet of the pressure chamber. A control unit may be in communication with the temperature sensors and the heat sources.

### TECHNICAL FIELD

The present disclosure relates to stainless steel substrates, and in particular, a manufacturing system and method to apply a protective coating on stainless steel substrates, such as those used on fuel cell bipolar plates.

### BACKGROUND

Fuel cells are used as an electrical power source in many applications. In particular, fuel cells are proposed for use in automobiles to replace internal combustion engines. A commonly used fuel cell design uses a solid polymer electrolyte (“SPE”) membrane or proton exchange membrane (“PEM”), to provide ion transport between the anode and cathode.

Fuel cells in general are an electrochemical device that converts the chemical energy of a fuel (hydrogen, methanol, etc.) and an oxidant (air or pure oxygen) in the presence of a catalyst into electricity, heat and water. Fuel cells produce clean energy throughout the electrochemical conversion of the fuel. Therefore, they are environmentally friendly because of the zero or very low emissions. Moreover, fuel cells are high power generating system from a few watts to hundreds of kilowatt with efficiencies much higher than conventional internal combustion engine. Fuel cells also have low noise production because of few moving parts.

In proton exchange membrane type fuel cells, hydrogen is supplied to the anode as fuel and oxygen is supplied to the cathode as the oxidant. The oxygen can either be in pure form (O₂) or air (a mixture of O₂ and N₂). PEM fuel cells typically have a membrane electrode assembly (“MEA”) in which a solid polymer membrane has an anode catalyst on one face, and a cathode catalyst on the opposite face. The anode and cathode layers of a typical PEM fuel cell are formed of porous conductive materials, such as woven graphite, graphitized sheets, or carbon paper to enable the fuel to disperse over the surface of the membrane facing the fuel supply electrode. Each electrode has finely divided catalyst particles (for example, platinum particles), supported on carbon particles, to promote oxidation of hydrogen at the anode and reduction of oxygen at the cathode. Protons flow from the anode through the ionically conductive polymer membrane to the cathode where they combine with oxygen to form water, which is discharged from the cell. The MEA is sandwiched between a pair of porous gas diffusion layers (“GDL”), which in turn are sandwiched between a pair of non-porous, electrically conductive elements or plates (i.e., flow field plates). The plates function as current collectors for the anode and the cathode, and contain appropriate channels and openings formed therein for distributing the fuel cell's gaseous reactants over the surface of respective anode and cathode catalysts. In order to produce electricity efficiently, the polymer electrolyte membrane of a PEM fuel cell must be thin, chemically stable, proton transmissive, non-electrically conductive and gas impermeable. In typical applications, fuel cells are provided in arrays of many individual fuel cell stacks in order to provide high levels of electrical power.

The electrically conductive plates currently used in fuel cells provide a number of opportunities for improving fuel cell performance. For example, these metallic plates typically include a passive oxide film on their surfaces wherein the electrically conductive coatings should be thin enough to minimize the contact resistance. Such electrically conductive coatings include gold and polymeric carbon coatings. The electrically conductive coating is applied to bipolar plates in a fuel cell in order to reduce or prevent corrosion during operation. Metallic bipolar plates may be subjected to corrosion during operation. The degradation mechanism includes the release of fluoride ions from the polymeric electrolyte. Metal dissolution of the bipolar plates typically results in release of iron, chromium and nickel ions in various oxidation states.

Currently, coatings may be applied to a stainless steel substrate (such as a bipolar plate for a fuel cell) using a vacuum deposition process such that an ellipsometer may measure the thickness of the coating as it is applied to the substrate via evaporation of the source coating material. However, in the inevitable circumstance where a surface imperfection exists on the surface of the substrate, the ellipsometer is unable to distinguish between an imperfection in the surface of the substrate and an unacceptable change in coating thickness. Moreover, the output from an ellipsometer is quite dependent on having an accurate model 28 to predict the coating thickness given that the model for the ellipsometer implements several different variables in order to determine the thickness of the coating. These different variables include, but are not limited to, evaporation rate, geometry of the source coating material, geometry of the substrate as well as the time duration of the evaporation process. The physical location of the ellipsometer in the coating line and possible locations where the measurements can be made using an ellipsometer also limit the fidelity of the measurements.

Accordingly, due to surface imperfections or inaccuracies for each of the multiple variables used in the model, the resulting output to determine thickness via a system using an ellipsometer does not provide sufficiently consistent and accurate results such that a coating is guaranteed to fall within the required thickness range. As indicated earlier, the coating thickness must be sufficiently thin to prevent excessive contact resistance while also protecting the substrate from excessive corrosion. An example preferred coating thickness range is generally measured in nanometers and therefore, accuracy in the measurement data is rather important.

Accordingly, there is a need for a manufacturing method and system to apply an even coating on a substrate within a predetermined thickness range such that the contact resistance of the substrate is maintained at acceptably low levels while also preventing excessive corrosion of the substrate.

### SUMMARY

The present disclosure provides for a manufacturing method and system for accurately applying a corrosion resistant coating onto a substrate in a vacuum coating process. In a first embodiment, the manufacturing method for manufacturing a coated substrate includes the steps of: (1) providing a substrate; (2) moving the substrate to a cleaning chamber; (3) cleaning the substrate in the cleaning chamber (optionally via a sputtering method); (4) moving the substrate from the cleaning chamber to a first pressure chamber; (5) determining a first temperature in the substrate in the first pressure chamber via a first temperature sensor while heating a first coating source material in the first pressure chamber; (6) adjusting a first heat source in the first pressure chamber based on a plurality of temperature data signals received from the first temperature sensor; and (7) moving the substrate out of the first pressure chamber.

In a second embodiment, the manufacturing method for manufacturing a coated substrate includes the steps of: (1) moving the substrate into a first pressure chamber (optionally via a conveyor); (2) determining a first temperature in the substrate in the first pressure chamber via a first temperature sensor while heating a first coating source material in the first pressure chamber; (3) adjusting a first heat source in the first pressure chamber based on a plurality of temperature data signals received from the first temperature sensor; and (4) moving the substrate out of the first pressure chamber (optionally via the conveyor).

A system for manufacturing a coated substrate may include at least one pressure chamber, a heat source, a temperature sensor and a control module. The pressure chamber is operatively configured to house the heat source, the temperature sensor and a substrate. The temperature sensor may be operatively configured to determine a temperature in the substrate while in the pressure chamber. The temperature sensor and the heat source may be in communication with a control module which implements a model. The control module may be operatively configured to determine coating thickness (via the model) based on a plurality of temperature signals received from the temperature sensor. The control module may also be operatively configured to communicate with the heat source in order to adjust the heat source based on the plurality of temperature signals. In each of the aforementioned examples, non-limiting embodiments for the system and methods of the present disclosure, it is understood that the substrate may, but not necessarily, be formed from stainless steel.

The present disclosure and its particular features and advantages will become more apparent from the following detailed description considered with reference to the accompanying drawings.

### BRIEF DESCRIPTION OF THE DRAWINGS

These and other features and advantages of the present disclosure will be apparent from the following detailed description, best mode, claims, and accompanying drawings in which:

FIG. 1A is a top view of a bipolar plate used in a fuel cell.

FIG. 1B is a schematic side view of the stainless steel substrate of FIG. 1 (bipolar plate) having a coating.

FIG. 2 is a schematic drawing for the manufacturing system for the present disclosure.

FIG. 3 is a graph illustrating an example, non-limiting relationship between temperature (in the chamber or in the substrate) and the thickness of the coating.

FIG. 4 is an example, non-limiting flowchart which illustrates non-limiting example methods of manufacture for the present disclosure.

Like reference numerals refer to like parts throughout the description of several views of the drawings.

### DETAILED DESCRIPTION

Reference will now be made in detail to presently preferred compositions, embodiments and methods of the present disclosure, which constitute the best modes of practicing the present disclosure presently known to the inventors. The figures are not necessarily to scale. However, it is to be understood that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

Except in the examples, or where otherwise expressly indicated, all numerical quantities in this description indicating amounts of material or conditions of reaction and/or use are to be understood as modified by the word “about” in describing the broadest scope of the present disclosure. Practice within the numerical limits stated is generally preferred. Also, unless expressly stated to the contrary: percent, “parts of,” and ratio values are by weight; the description of a group or class of materials as suitable or preferred for a given purpose in connection with the present disclosure implies that mixtures of any two or more of the members of the group or class are equally suitable or preferred; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

The terms “comprising”, “consisting of”, and “consisting essentially of” can be alternatively used. Where one of these three terms is used, the presently disclosed and claimed subject matter can include the use of either of the other two terms.

Throughout this application, where publications are referenced, the disclosures of these publications in their entireties are hereby incorporated by reference into this application to more fully describe the state of the art to which this present disclosure pertains.

The following detailed description is merely exemplary in nature and is not intended to limit the present disclosure or the application and uses of the present disclosure. Furthermore, there is no intention to be bound by any theory presented in the preceding background or the following detailed description.

The present disclosure provides, in part, a manufacturing method to apply a thin coating 56 on a substrate 10. The substrate 10 may, but not necessarily, be a stainless steel substrate 10 for use as a bipolar fuel cell plate 54. Bipolar plates used in fuel cells require a protective coating 56 to prevent corrosion. However, despite the use of a coating 56, it is also desirable that contact resistance at the surface of the bipolar plate 54 stay at reduced levels despite any protective coating 56.

Stainless steel may be implemented given that stainless steel has a relatively low cost with high electrical and thermal conductivity, good mechanical properties, and ease of machining. Moreover, stainless steel bi-polar plates may be quickly manufactured in high volumes using a stamping process before or after the (stainless steel) substrate 10 is coated. As indicated, a fuel cell bipolar plate 54 may be coated with corrosion resistant material prior to the stamping process. While there are many different ways to apply a coating 56 to a stainless steel substrate 10, one process to apply a thin coating 56 to the substrate 10 is the vacuum deposition method.

One of the common methods to apply a coating 56 to a stainless steel substrate 10 is thermal evaporation. This is a form of thin film deposition, which is a vacuum technology for applying coatings of pure materials to the surface of various objects. The coatings, also called films, are usually in the thickness range of angstroms to nanometers and can be a single material, or can be multiple materials in a layered structure.

The materials to be applied with thermal evaporation techniques can be pure atomic elements including both metals and non-metals, or can be molecules such as oxides and nitrides. The object to be coated is referred to as the substrate 10, and can be any of a wide variety of things such as: a bipolar plate 54 in a fuel cell or fuel cell stack, semiconductor wafers, solar cells, optical components, or many other possibilities.

Thermal evaporation involves heating a solid material 72 inside a high vacuum chamber wherein the temperature in the chamber is sufficiently high such that vapor pressure is created inside the chamber. Inside the vacuum, even a relatively low vapor pressure is sufficient to raise a vapor cloud inside the chamber. This evaporated material now constitutes a vapor stream, which traverses the chamber and hits the substrate 10, sticking to the substrate 10 as a coating 56 or film.

Since, in most instances of thermal evaporation processes, the material 72 is heated to its melting point and is liquid, the coating source material 72 is usually located in the bottom of the chamber, often in some sort of upright crucible. The vapor then rises above this bottom source, and the substrates 10 may be held inverted in appropriate fixtures at the top of the chamber. The surfaces intended to be coated may be facing down toward the heated source material 72 to receive their coating.

E-Beam Evaporation is another example of a thermal evaporation process that may be implemented to apply a coating 56 to a substrate 10. This process involves the step of heating up the coating material 72 and involves high voltage (usually 10,000 volts). The E-Beam systems always include extra safety features. The source itself is usually an E-Beam “gun,” where a small and very hot filament boils off electrons which are then accelerated by the high voltage, forming an electron beam with considerable energy.

This electron beam is magnetically directed into the crucible where the coating material 72 awaits. At the standard 10 kV, even 0.1 amp of this beam current will deliver 1 kilowatt of concentrated power, and this heats the coating material 72, which is contained in a hearth which is water cooled to prevent its own destruction. It is understood that these commercially available E-Beam guns may have multiple crucibles within a chamber and thus be capable of holding several different materials at one time and easily switch between them for multi-layer processing.

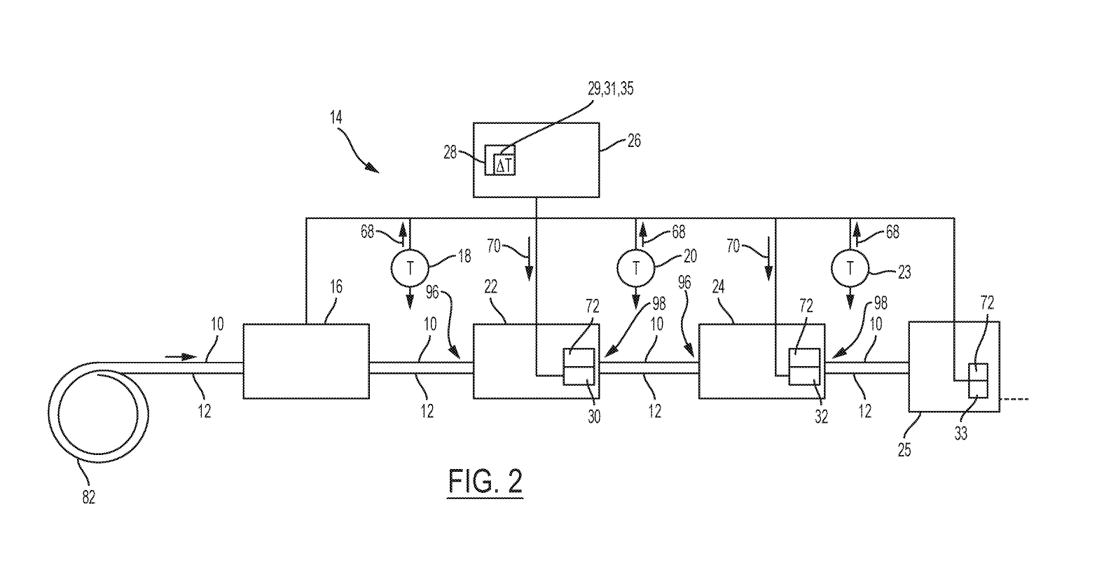

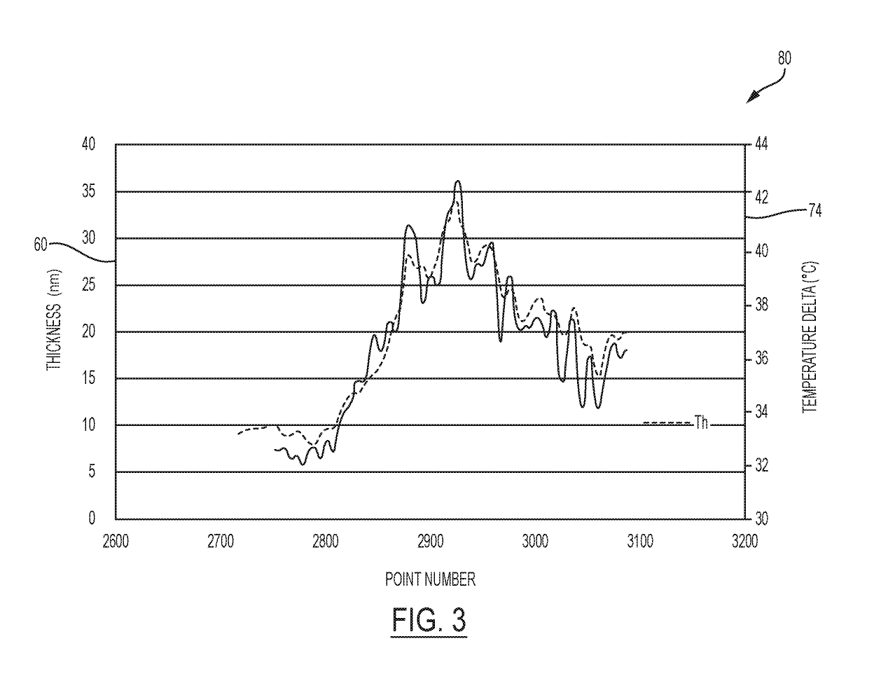

Regardless of which thermal evaporation process is used, the present disclosure contemplates that a temperature sensor 18, 20, 23, such as but not limited to an infrared line camera or a temperature sensor, may be disposed before and after each pressure chamber 22, 24, 25. The temperature sensor 18, 20, 23 may measure the temperature across the entire width of the substrate 10 in order to help determine the thickness of the coating 56 (via a model 28 in the control unit 26). As shown in FIGS. 2 and 3, the system and method of the present disclosure implements a model 28 which correlates the temperature readings (difference in temperature before and after each pressure chamber) with the thickness of the coating 56 applied at that particular pressure chamber. The temperature change 29, 31 would be calculated as the difference between the substrate temperature before at least a portion 7 of a substrate enters a pressure chamber and the substrate temperature after at least a portion 7 of the substrate leaves the same pressure chamber. The coating thickness would be the amount of coating material applied at that particular pressure chamber.

The model 28 for a system 14 of the present disclosure would be developed for the specific application—one non-limiting example is the application of a coating for a bipolar fuel cell plate. For example, experimental data may be gathered where temperatures changes and corresponding coating thicknesses are initially measured for specific materials—source coating material 72 as well as substrate material. Based on these gathered data points, a user may identify the relationship between temperature and coating thickness for particular materials such as by drawing a line through the data points. Accordingly, a model 28 may then be created (for use in the control module unit) such that the coating thickness 60 may be accurately estimated based on temperature readings 68—difference in the temperature readings 29, 31.

Therefore, when a system 14 of the present disclosure is in operation, temperature and thickness may be continuously monitored especially where a continuous strip of substrate material is used—as shown in FIG. 2. For example, when it appears that the thickness and temperature readings are drifting toward the outer bounds of a predetermined acceptable temperature/thickness range at the first pressure chamber 22, due to a first temperature change 29 received from the first pressure chamber 22, then an operator or the system/method/model may adjust the temperature in the next available pressure chamber(s) 24 by adjusting the affected heat source 32 (such as a flame in the pressure chamber) via temperature adjustment output signal 70 to increase or decrease the amount of coating material applied to the substrate 10 or portion 7 of a substrate in the next available pressure chamber 24. The first temperature change 29 is defined as the difference in temperature in the substrate prior to entering the first pressure chamber 22 at temperature sensor 18, and the temperature in the substrate 10 after leaving the first pressure chamber 22 at temperature sensor 20.

In yet another example, a second temperature change 31 is determined at the second pressure chamber 24. Similarly, the second temperature change 31 is defined as the difference in temperature in the substrate 10 prior to entering the second pressure chamber 24 at temperature sensor 20, and the temperature in the substrate 10 after leaving the second pressure chamber 24 at temperature sensor 23. The first and second temperature changes 29, 31 may be calculated at the model 28 in the control unit 26. Similarly, when it appears that the thickness and temperature readings are drifting toward the outer bounds of a predetermined acceptable temperature/thickness range at the second pressure chamber 24, due to a second temperature change 31 received from the second pressure chamber 24, then an operator or the system/method/model may adjust the temperature in the next available pressure chamber(s) (shown as 25 in this example) by adjusting the affected heat source 33 (such as a flame in the pressure chamber) via temperature adjustment output signal 70 to increase or decrease the amount of coating material applied to the substrate 10 or portion 7 10′ of a substrate 10 in the next available pressure chamber 25.

While three pressure chambers 22, 24, 25 are shown in FIG. 2, it is also understood that as little as one pressure chamber may be used or as many as 4 to 5+ pressure chambers may be used in accordance with the present disclosure. It is also understood that cleaning chamber 16 may not always be needed depending on the particular application. Cleaning chamber 16 would be used in applications such as coating a fuel cell bipolar plate given the need to remove oxide from the substrate surface just prior to the deposition process. In applications outside of bipolar plates, cleaning chamber 16 may not be a necessary aspect of the present disclosure. It is also understood that cleaning chamber 16 may involve one of a variety of different cleaning processes—sputtering, plasma, solution chemistry, etc.

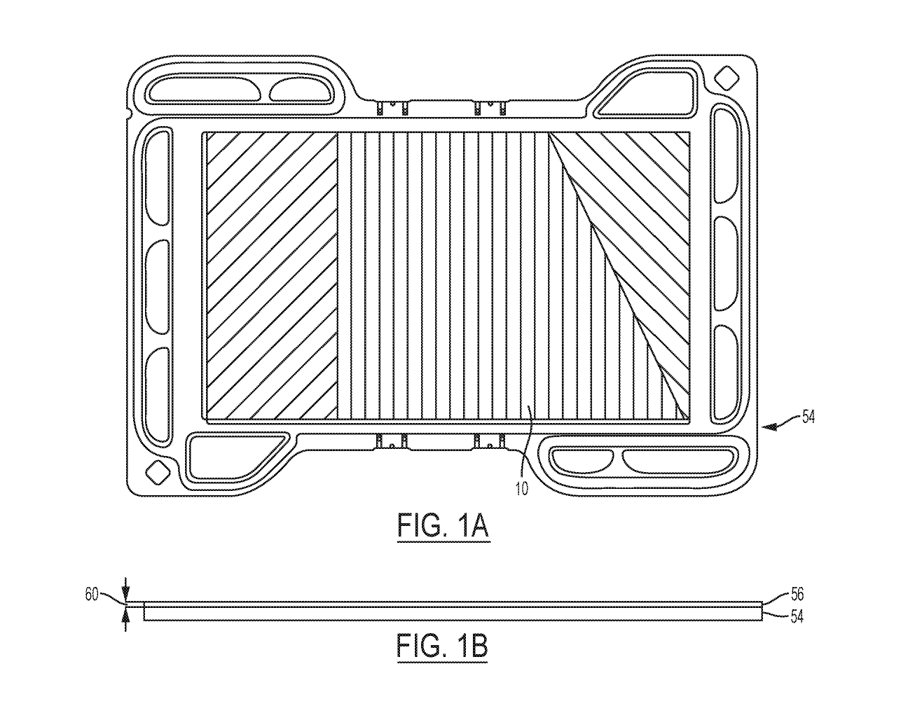

Referring again to FIG. 2, a non-limiting example schematic system 14 for manufacturing a coated substrate 10 of FIG. 1B is shown. The system includes at least one pressure chamber 22, 24, 25, a heat source 30, 32, 33 a temperature sensor 18, 20, 23 and a control unit 26. In FIG. 2, a first pressure chamber 22 is shown as well as a second and third pressure chamber 24, 25 and a cleaning chamber 16. Each of the first, second, and third pressure chambers 22, 24, 25 is operatively configured to house a heat source 30, 32, and at least a portion 7 of substrate 10 as it passes through each pressure chamber 22, 24. It is understood that the substrate 10 may be a continuous strip of material such that a portion 7 of the substrate 10 is in each pressure chamber at a time—as shown in FIG. 2. However, it is also understood that the substrate may be alternatively be a smaller component such that the entire substrate could enter and leave each pressure chamber.

Each of the temperature sensors 18, 20, 23 shown in FIG. 2 may, but not necessarily, be an in-line sensor which determines the temperature across the width of the substrate 10. As shown, a temperature sensor 18, 20, 23 is disposed before and after each pressure chamber 22, 24, 25 such that the difference 29, 31 in substrate temperature is measured before and after each pressure chamber 22, 23, 25. The temperature difference (delta T) 29, 31 may be calculated by model 28 used by the control unit 26. The model 28 then determines the thickness 60 of the coating 56 based on the temperature difference 29, 31—difference between the temperature readings taken before and after an associated pressure chamber. Temperature readings are provided via each temperature sensor 18, 20, 23 which may send a temperature signal 68 to the control unit 26.

The control unit 26 implements a model 28 to determine whether the coating thickness 60 is in the appropriate pre-determined range based on the (difference between) the temperature signal(s) received. The model 28 and the control unit 26 are then operatively configured to send an output heat adjustment signal 70 to the next available heat source 30, 32, 33—first heat source 30 or second heat source 32 or third heat source 33 in order to increase or reduce the temperature in the next available pressure chamber. It is understood that the temperature within the next available pressure chamber directly affects the evaporation rate of the coating material which then affects the coating thickness 60 applied on the substrate 10 at that next available pressure chamber 22, 24, 25. Therefore, a temperature difference may calculated by the model upon receiving the temperature signals to determine the coating thickness applied at a particular pressure chamber 22, 24, 25, then the system and method of the present invention may adjust the temperature at the next available pressure chamber—for example, second pressure chamber 24 or third pressure chamber 25 depending upon which pressure chamber was used to extract the relevant data—to make sure that the resulting coating thickness 60 falls within a desired range once the substrate passes through the next available pressure chamber.

As shown in FIG. 2, each of the first, second and third temperature sensors 18, 20, 23, as well as the first, second, and third heat sources 30, 32, 33 may be in communication with a control unit 26. The control unit 26 determines coating thickness 60 based on the first and second temperature changes 29, 31 in the substrate 10. The first temperature change 29 is calculated via temperature data extracted from the first pressure chamber 22—temperature of the substrate 10 at the inlet 96 of the first pressure chamber 22 and the temperature of the substrate 10 at the outlet 98 of the first pressure chamber 22. The second temperature change 31 is calculated via temperature data extracted from the second pressure chamber 24—temperature of the substrate 10 at the inlet 96 of the second pressure chamber 24 and the temperature of the substrate 10 at the outlet 98 of the second pressure chamber 24. Similarly, the third temperature change 35 may be calculated via temperature data extracted from the third pressure chamber 25—temperature of the substrate 10 at the inlet 96 of the third pressure chamber 25 and the temperature of the substrate 10 at the outlet 98 of the second pressure chamber 25. As indicated, the various temperature changes (first, second or third temperature change 29, 31, 35) may be calculated using a temperature signal 68 from each temperature sensor 18, 20, 23 before (inlet 96) and after (outlet 98) the chosen pressure chamber.

The detection of the first, second and third temperature changes 29, 31, 35 before and after each respective pressure chamber 22, 24, 25 as well as the resulting heat adjustments for next available pressure chambers 24, 25 may also occur in real time. That is, as temperature data 68 from each line sensor 18, 20, 23 before/after each of the chambers 22, 24, 25 is fed into the model 28, the next available heat source 32, 33 may be automatically adjusted according to the temperature change 29, 31, 35 obtained from the preceding pressure chamber 22, 24. For example, if the model 28/control unit 26 determines that the coating thickness 60 for the substrate 10 in the first pressure chamber 22 is starting to drift towards the outer bounds of the acceptable range (too thick or too thin), then the control unit 26 may adjust the temperature in the second pressure chamber 24 (via an output heat adjustment signal 70 to the heat source 32) in order to adjust the coating thickness 60 applied at the second pressure chamber so as to have the correct resulting thickness. The coating 56 applied in the second pressure chamber may be decreased (via a decreased temperature by reducing the heat source 32 in the second pressure chamber 24) if the first temperature change 29 data from the first pressure chamber show that the coating thickness 60 may be getting too thick. However, if the first temperate change 29 data from the first pressure chamber 22 show that the coating thickness 60 may be too thin at the first pressure chamber 22, then the control module unit 26 will send a heat adjustment signal 70 to the second (or next available) heat source 32 in the second (or next available) pressure chamber 24 so that the heat source 32 is increased to increase the evaporation rate to provide a thicker coating 60 at the second or next available pressure chamber 24. The same process is repeated each time there is a next available pressure chamber 24, 25 which can be used to keep the overall coating thickness 60 within an acceptable range.

In summary, where the coating thickness 60 needs to be increased due to the detection of unacceptably low temperature changes, the model 28 and control unit 26 will send a heat adjustment output signal 70 to the next available heat source 32, 33 so as to increase the temperature of the substrate 10 at the next available pressure chamber 24, 25 if it has been determined that the coating thickness 60 should be adjusted. It is understood that where only one pressure chamber is used, then a substrate 10 may be repeatedly inserted into the same pressure chamber (using temperature change data 29) in order to obtain the desired thickness 60.

In general, as the coating source material 72 heats up, more coating material will be applied to the substrate 10 in a pressure chamber 22, 24, 25 via an evaporation process of the source coating material 72. In contrast, where the end result coating thickness 60 needs to decreased due to the detection of unacceptably high temperature signals 68 (such as at a first pressure chamber 22), the model 28 and control unit 26 will send a heat adjustment output signal 70 to the next available heat source 30, 32, 33 to decrease the heat generated by the next available heat source 30, 32, 33 in order to reduce the temperature of the substrate 10 at that next available pressure chamber. As the coating source material 72 cools down, less coating material will be applied to the substrate 10 in the chamber via a relatively decreased evaporation process of the source coating material 72. These quick, efficient and real-time adjustments to the manufacturing process reduces the need to scrap a part because the coating process may be immediately adjusted before irreversible damage occurs to the stainless steel substrate 10.

With reference to FIG. 3, a graph 80 is shown which demonstrates example data points which illustrate an example relationship between substrate temperature 74 and coating thickness 60. As shown, as the substrate temperature change 74 increases, the coating thickness 60 at that particular pressure chamber also increases. A non-limiting example acceptable coating thickness 60 range is approximately 3 nanometers to 100 nanometers. Moreover, an example, non-limiting temperature change range 74 which may correspond to the thickness may be approximately 25 degrees Celsius to approximately 100 degrees Celsius.

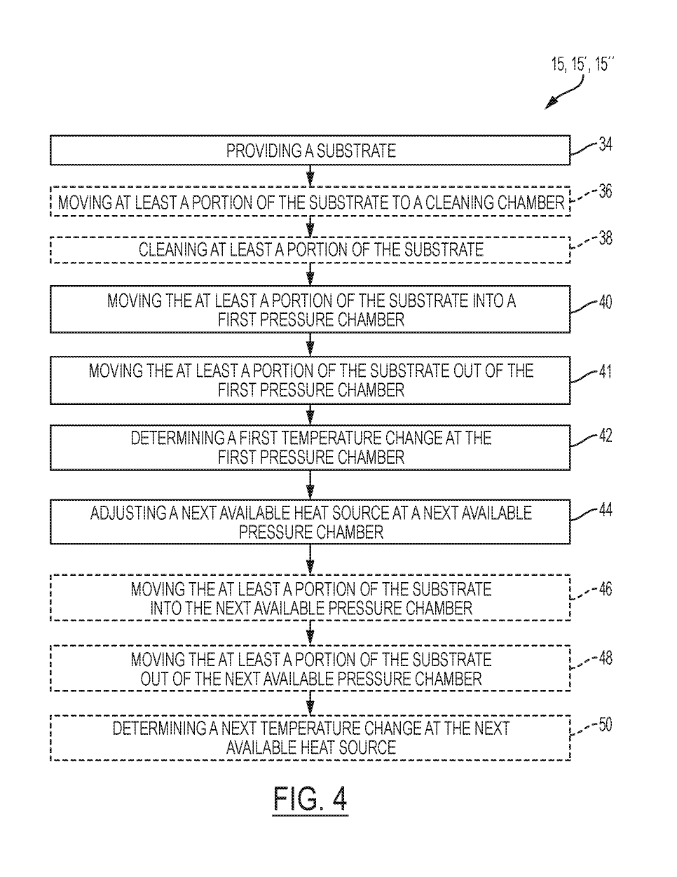

Referring now to FIG. 4, an example, non-limiting flow chart is provided which illustrates various embodiments of the manufacturing method 15, 15′ of the present disclosure. As shown in the flowchart, the manufacturing method 15 for accurately applying a corrosion resistant coating 56 onto a substrate 10 in a vacuum coating process includes several steps. In a first embodiment, the manufacturing method for manufacturing a coated substrate includes the steps of: (1) providing a substrate (on an optional conveyor) where the substrate may be deployed from a coil of the substrate material 34; (2) moving at least a portion of the substrate to a cleaning chamber via the optional conveyor 36; (3) cleaning at least a portion of the substrate in the cleaning chamber (optionally via a sputtering method) 38; (4) moving the substrate or a portion of the substrate from the cleaning chamber to a first pressure chamber and applying a first coating layer to the substrate or at least a portion of the substrate 40; (5) moving the substrate or a portion of the substrate out of the first pressure chamber 41; (6) determining a first temperature change in the substrate at the first pressure chamber via a pair of temperature sensors 42; (7) adjusting a next available heat source at a next available pressure chamber 44; and (7) moving the substrate or a portion of the substrate into the next available pressure chamber (second pressure chamber 24) and applying a next (or second) coating layer to the substrate or at least a portion of the substrate 46;(8) moving the substrate or a portion of the substrate out of the next available pressure chamber (second pressure chamber 24) 48; (9) determining a second temperature change at the next available heat source 50. It is understood that steps 46, 48, 50 are steps that are only required if a second pressure chamber (as that shown in FIG. 2) is employed. Therefore steps 46, 48, 50 are shown in phantom. Moreover, it is also understood that steps 36 and 38 may also be optional steps to an alternative method 15′ of the present disclosure given that not all applications may require substrate 10 to be cleaned immediately (oxide removal) before the coating process in the pressure chambers. As a result, steps 36, and 38 are also shown in phantom given that these steps may not be used for second embodiment method 15′. It is understood that the end coating thickness layer (the first and second coating layers when only first and second pressure chambers are used) may, but not necessarily, have a total coating thickness within a range of 3 nm to 100 nm. This coating thickness may be desirable where bipolar plates are being coated.

Referring again to FIG. 4, a third embodiment manufacturing method 15″ for manufacturing a coated substrate does not require cleaning steps, nor does it require a second pressure chamber. Therefore, in the third embodiment manufacturing method 15″, the method includes the steps of: (1) providing a substrate 34; (2) moving the substrate or at least a portion of the substrate into a first pressure chamber and applying a first coating layer to the substrate or at least a portion of the substrate 40; (3) moving the substrate or at least a portion of the substrate out of the first pressure chamber 41; (4) determining a first temperature change in the substrate or portion of the substrate at the first pressure chamber 42; and (5) adjusting a next available heat source at the next available pressure chamber. It is understood that this third embodiment method contemplates that the same first pressure chamber may be used repeatedly where the temperature (heat source in the first pressure chamber 22) is adjusted between each use of the pressure chamber to obtain the correct coating thickness 60. Accordingly, steps 36, 38, 40, 46, 48, and 50 are shown in phantom in the flow chart of FIG. 4 given that these steps would not be required in the third embodiment method 15″. It is understood that the end resulting coating thickness layer(s) may, but not necessarily have a total coating thickness within a range of 3 nm to 100 nm. This coating thickness may be desirable where bipolar plates are being coated.

In each of the aforementioned example non-limiting embodiments for the system and method of the present disclosure, it is understood that the substrate 10 may, but not necessarily, be formed from stainless steel. Optionally, the substrate may be also be in the form of a specific component such that the substrate may be completely housed in each pressure chamber. Again, FIG. 2 shows a continuous strip of substrate material rather than a specific component.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A system for manufacturing a coated substrate, the system comprising:
a pressure chamber operatively configured to receive a substrate;
a heat source disposed within the pressure chamber;
a first temperature sensor disposed at an inlet of the pressure chamber and a second temperature sensor disposed at an outlet of the pressure chamber, and
a control module in communication with a next available heat source, and the first and second temperature sensors.

2. The system as defined in claim 1 wherein the control module is operatively configured to determine a coating thickness based on a first temperature signal received from the first temperature sensor and a second temperature signal received from the second temperature sensor.

3. The system as defined in claim 2 wherein the control module is operatively configured to adjust the next available heat source based on the first and second temperature signals.

4. A method for manufacturing a corrosion resistant substrate, the method comprising the steps of:
providing at least a portion of a substrate on a conveyor;
moving the at least a portion of the substrate to a cleaning chamber via the conveyor;
cleaning the at least a portion of the substrate in the cleaning chamber;
moving the at least a portion of the substrate to a first pressure chamber;
moving the at least a portion of the substrate out of the first pressure chamber;
determining a first temperature change in the at least a portion of the substrate at the first pressure chamber; and
adjusting a second heat source at a second pressure chamber based on the first temperature change.

5. The method of claim 4 further comprising the steps of:
moving the at least a portion of the substrate into the second pressure chamber;
moving the at least a portion of the substrate out of the second pressure chamber; and
determining a second temperature change in the at least a portion of the substrate in the second pressure chamber.

6. The manufacturing method of claim 4 wherein the at least a portion of the substrate is coated via an evaporation process in the first pressure chamber.

7. The manufacturing method of claim 5 wherein the at least a portion of the substrate is coated via an evaporation process in the second pressure chamber.

8. The manufacturing method of claim 5 wherein the substrate is formed from stainless steel.

9. The manufacturing method of claim 7 wherein the substrate is a continuous strip of material.

10. The manufacturing method of claim 4 wherein a model in a control unit determines determining the first temperature change.

11. The manufacturing method of claim 10 wherein the model in the control unit sends a temperature adjustment output signal to a second heat source in the second pressure chamber based on the first temperature changes.

12. A method for manufacturing a corrosion resistant substrate, the method comprising the steps of:
providing at least a portion of a substrate on a conveyor;
moving the at least a portion of the substrate to a first pressure chamber and applying a first coating layer to the at least a portion of the substrate;
moving the at least a portion of the substrate out of the first pressure chamber;
determining a first temperature change in the at least a portion of the substrate at the first pressure chamber; and
adjusting a second heat source at a second pressure chamber based on the first temperature change.
moving the at least a portion of the substrate into the second pressure chamber and applying a second coating layer to at least a portion of the substrate;
moving the at least a portion of the substrate out of the second pressure chamber; and
determining a second temperature change in the at least a portion of the substrate at the second pressure chamber.

13. The manufacturing method of claim 10 wherein the at least a portion of the substrate is coated via an evaporation process in the first pressure chamber and the second pressure chamber.

14. The manufacturing method of claim 10 wherein the at least a portion of the substrate is formed from stainless steel.

15. The manufacturing method of claim 10 wherein the substrate is a continuous strip of material.

16. The manufacturing method of claim 10 wherein the first and second temperature sensors are line sensors.

17. The manufacturing method of claim 10 wherein a model in a control unit determines determining the first and second temperature changes.

18. The manufacturing method of claim 15 wherein the control unit sends a temperature adjustment output signal to a second heat source in the second pressure chamber based on the first and second temperature changes.

19. The manufacturing method of claim 12 wherein the first and second coating layers has a total coating thickness within a range of 3 nm to 100 nm.
